(19) United States
(12) Patent Application Publication
(10) Pub. No.: US 2011/0269295 A1
(43) Pub. Date: Nov. 3, 2011

(54) Method of Forming a Semiconductor Wafer that Provides Galvanic Isolation

(76) Inventors: Peter J. Hopper, San Jose, CA (US); William French, San Jose, CA (US)

(21) Appl. No.: 12/771,829

(22) Filed: Apr. 30, 2010

(51) Int. Cl. H01L 21/78

(52) U.S. Cl. 438/458; 438/459; 257/E21.599

(57) ABSTRACT

A semiconductor wafer that provides galvanic isolation is formed in a very cost efficient manner by attaching a non-conductive wafer to a silicon wafer to form a hybrid wafer, and then simultaneously wet etching a large number of hybrid wafers to form a thin non-conductive wafer that is attached to a thick silicon wafer. After a large number of high-voltage devices have been formed on the thin non-conductive wafer, the thick silicon wafer is thinned or removed so that the hybrid wafer is suitable for packaging.

### BACKGROUND OF THE INVENTION

1. Field of the Invention

The present invention relates to a method of forming a semiconductor wafer and, more particularly, to a method of forming a semiconductor wafer that provides galvanic isolation.

2. Description of the Related Art

A quartz wafer is well-known, and is commonly used in the fabrication of a number of semiconductor devices. Quartz wafers are non-conductive and, as a result, are an ideal surface for forming very high voltage (e.g., 5,000V) semiconductor devices, such as microelectromechanical system (MEMS) devices, that require galvanic isolation.

One of the drawbacks of quartz wafers, however, is wafer thinning. Both quartz wafers and single-crystal silicon wafers are typically commercially available in thicknesses of, for example, 500 μm to 750 μm. The wafers are processed at this thickness until a large number of semiconductor devices have been formed on the wafer.

However, after the devices have been formed on the wafers, but before dicing and die packaging, the wafers are thinned with a grinding wheel to have a thickness of approximately 250 μm to 400 μm to be suitable for packaging. Grinding wheels can generally thin about 20,000 single-crystal silicon wafers to a suitable thickness before needing to be replaced.

By contrast, a grinding wheel can generally thin only about 200 quartz wafers to a suitable thickness before needing to be replaced. Thus, since so few quartz wafers can be thinned with a grinding wheel before the grinding wheel needs to be replaced, it is significantly more expensive to fabricate high-voltage semiconductor devices on a quartz wafer than it is to fabricate low-voltage semiconductor devices on a single-crystal silicon wafer.

Rather than utilizing a quartz wafer, a layer of silicon dioxide can be deposited by chemical vapor deposition on the top surface of a conventional single-crystal silicon wafer. To achieve a reasonable level of galvanic isolation, the layer of deposited silicon dioxide must be relatively thick. For example, 5,000V of isolation require a layer of deposited silicon dioxide that is approximately 25 μm thick.

However, it also becomes quite expensive to deposit layers of silicon dioxide in excess of approximately 10 μm. Thus, since it is quite expensive to deposit a relatively thick layer of silicon dioxide on a silicon wafer, it is significantly more expensive to fabricate high-voltage semiconductor devices on thick layers of deposited silicon dioxide than it is to fabricate low-voltage semiconductor devices on a single-crystal silicon wafer.

As a result, there is a need for a method of forming a semiconductor wafer that can provide galvanic isolation for high-voltage semiconductor devices in a cost efficient manner.

### BRIEF DESCRIPTION OF THE DRAWINGS

FIGS. 1-12 are cross-sectional views illustrating an example of a method of forming a semiconductor wafer 100 that provides galvanic isolation in accordance with the present invention.

### DETAILED DESCRIPTION OF THE INVENTION

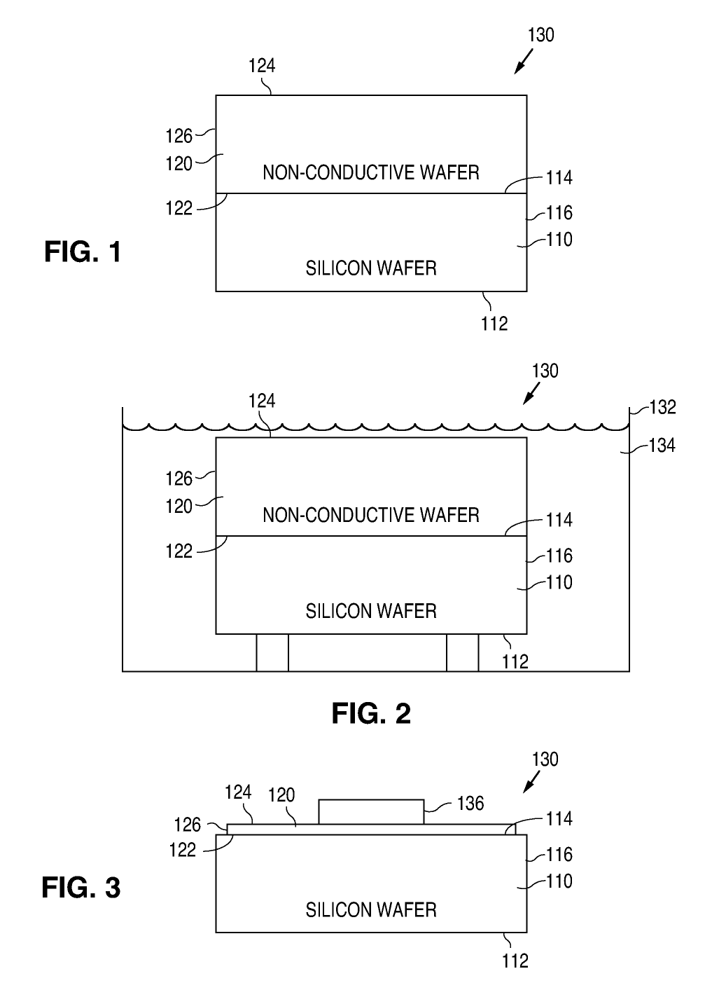

FIGS. 1-12 show cross-sectional views that illustrate an example of a method of forming a semiconductor wafer 100 that provides galvanic isolation in accordance with the present invention. As described in greater detail below, the present invention forms a semiconductor wafer that provides galvanic isolation in a very cost efficient manner by attaching a non-conductive (e.g., quartz) wafer to a silicon wafer to form a hybrid wafer, and then simultaneously wet etching a large number of hybrid wafers to form a thin non-conductive wafer that is attached to a thick silicon wafer. After a large number of high-voltage devices have been formed on the thin non-conductive wafer, the thick silicon wafer is thinned or removed so that the hybrid wafer is suitable for packaging.

As shown in FIG. 1, the method of the present invention utilizes a conventional silicon wafer 110 that has a bottom surface 112, a top surface 114, and a side wall surface 116. The method also utilizes a conventional non-conductive wafer 120 that has a bottom surface 122, a top surface 124, and a side wall surface 126.

The silicon wafer 110 has a conventional commercially available thickness, e.g., approximately 400 μm to 750 μm thick, and can be implemented with, for example, single-crystal silicon. The non-conductive wafer 120 also has a conventional commercially available thickness, e.g., approximately 500 μm to 750 μm thick, with the thinnest commercially available wafer being preferred. The non-conductive wafer 120 can be implemented with, for example, quartz or borosilicate glass (BSG).

As further shown in FIG. 1, the method begins by attaching the bottom surface 122 of the non-conductive wafer 120 to the top surface 114 of the silicon wafer 110 in a conventional manner to form a hybrid wafer 130. For example, the non-conductive wafer 120 can be attached to the silicon wafer 110 using the well-known anodic bonding process.

As shown in FIG. 2, after the hybrid wafer 130 has been formed, the hybrid wafer 130 is placed in a tank 132 filled with an etchant 134 and wet etched so that all of the top surface 124 of the non-conductive wafer 120 is wet etched. One or more wet etches using one or more etchants in one or more tanks can be used until the thickness of the non-conductive wafer 120 reaches a final thickness. The etch or etches can be timed to achieve the final thickness, or the thickness of the hybrid wafer 130 can be measured in-situ.

The etchant 134 used in an etch can be implemented with any conventional etch chemistry that wet etches substantially more of the non-conductive wafer 120 than the silicon wafer 110. In the preferred embodiment, the silicon wafer 110 is inert to the etchant 134 such that the etchant 134 etches none of the silicon wafer 110.

For example, the hybrid wafer 130 can be wet etched in a tank with a buffered hydrogen fluoride (HF) solution for a first predetermined period time, and then wet etched in a tank with a dilute HF solution for a second predetermined period of time to etch the non-conducting wafer 120 to the final thickness. The silicon wafer 110 is inert to these two HF etch chemistries and thus is not etched by these two HF etch chemistries. Ammonium fluoride can alternately be used. In the present invention, the final thickness of the non-conductive wafer 120 after the wet etch is in the approximate range of 100 μm to 300 μm, and depends on a number of factors that are discussed below.

As shown in FIG. 3, after the non-conductive wafer 120 has been etched to the final thickness, the hybrid wafer 130 is removed from the tank 134, rinsed, and conventionally prepared for semiconductor processing. As further shown in FIG. 3, the side wall 126 of the non-conductive wafer 120 is also etched, but only by a small amount. This is because the stress in the layers limits the side wall etch. For example, less than 0.5 mm of the side wall 126 is etched from a wafer originally having a maximum cross-sectional width of 200 mm.

Once the hybrid wafer 130 has been conventionally prepared for semiconductor processing, a large number of high-voltage structures 136 that each requires galvanic isolation, e.g., 5,000V, is formed to touch the top surface 124 of the non-conducting wafer 120. (Only one high-voltage structure 136 is shown for clarity.) The high-voltage structures 136 can be formed in a number of different ways.

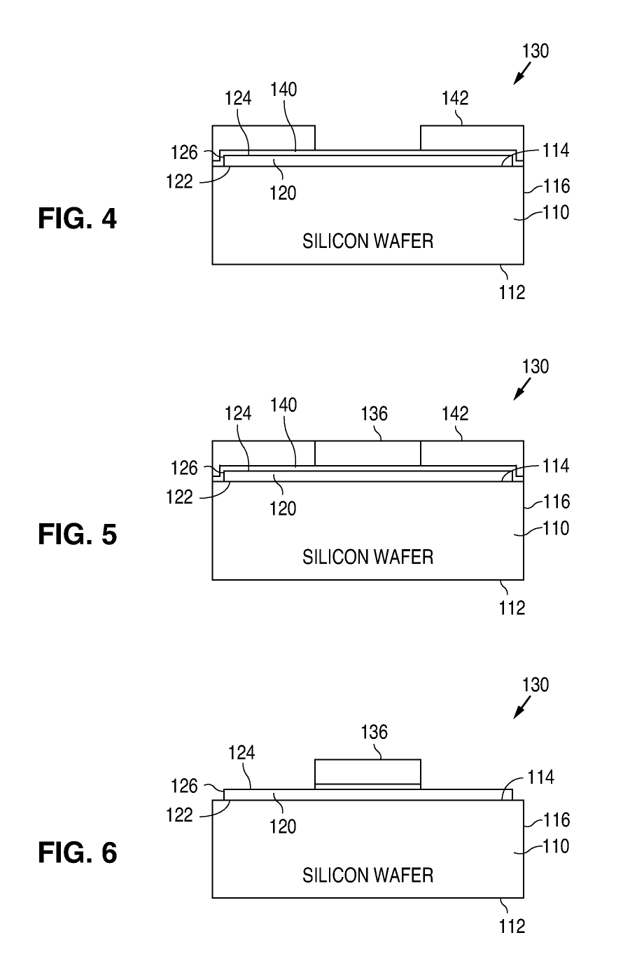

As shown in FIG. 4, in a first embodiment, a seed layer 140 can be formed to touch the top surface 124 of the non-conductive wafer 120. For example, the seed layer 140 can be formed by depositing 300 Å of titanium, 3000 Å of copper, and 300 Å of titanium. (The seed layer 140 can also include a barrier layer to prevent copper electromigration if needed.) Once the seed layer 140 has been formed, a plating mold 142 is formed on the top surface of the seed layer 140.

As shown in FIG. 5, following the formation of the plating mold 142, the top titanium layer is stripped and copper is deposited by electroplating to form the high-voltage structure 136. As shown in FIG. 6, after the electroplating, the plating mold 142 and the underlying regions of the seed layer 140 are removed.

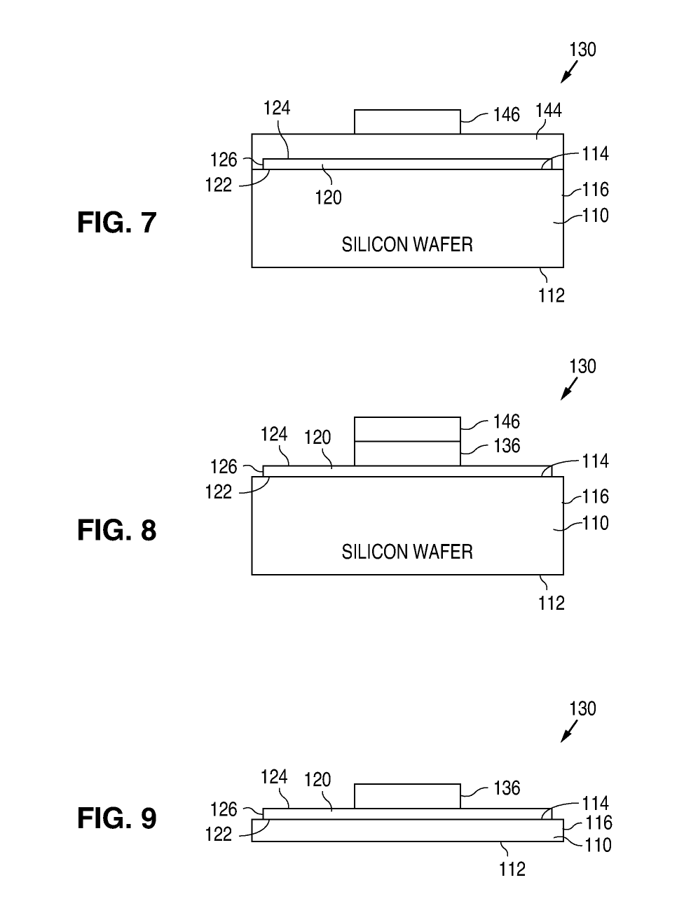

Alternately, in a second embodiment, as shown in FIG. 7, the high-voltage structure 136 can be formed by depositing a metal layer 144 that touches the top surface 124 of the non-conductive wafer 120. The metal layer 144 can include, for example, a layer of titanium (e.g., 100 Å thick), a layer of titanium nitride (e.g., 200 Å thick), a layer of aluminum copper (e.g., 1.2 μm thick), a layer of titanium (e.g., 44 Å thick), and a layer of titanium nitride (e.g., 250 Å thick). Once the metal layer 144 has been formed, a mask 146 is formed and patterned on the top surface of the metal layer 144.

As shown in FIG. 8, following the formation and patterning of the mask 146, the metal layer 144 is etched to remove the exposed regions of the metal layer 144 and form the high-voltage structure 136. The mask 146 is then removed. Additional steps can be performed, such as forming an overlying passivation layer such that the high-voltage structure 136 includes a conductive member and a non-conductive structure. Further, additional high-voltage elements can be formed, such as by forming one or more additional metal structures with one or more layers of inter-metal dielectric, and an overlying passivation layer.

As shown in FIG. 9, after the high-voltage structures 136 have been formed, the bottom surface 114 of the hybrid wafer 130 is thinned using a conventional grinding wheel so that the hybrid wafer 130 is suitable for packaging. The final thickness of the hybrid wafer 130 must be less than the maximum die thickness that the selected package can accommodate, and includes the final thickness of the non-conductive wafer 120, the thicknesses of the high-voltage structures 136 that are to-be-formed on the non-conductive wafer 120, and the remaining thickness of the silicon wafer 110.

For example, if a package can accommodate a maximum die thickness of approximately 350 μm, the non-conductive wafer 120 was thinned to a thickness of approximately 100 μm, and the high-voltage structure 136 has a thickness of approximately 50 μm, then the silicon wafer 110 of the hybrid wafer 130 must be thinned in a conventional manner to a thickness of approximately 200 μm so that the hybrid wafer 130 has a final thickness of approximately 350 μm to fit into the package.

On the other hand, if a package can accommodate a maximum die thickness of approximately 350 μm, the non-conductive wafer 120 was thinned to a thickness of approximately 300 μm, and the high-voltage structure 136 has a thickness of approximately 50 μm, then the silicon wafer 110 must be completely or substantially completely removed using a grinding wheel to allow the hybrid die 130 to fit into the package.

Thus, the final thickness of the non-conductive wafer 120 following the wet etch but before the high-voltage structures 136 have been formed is dependent upon the maximum die thickness that a package can accommodate, the final thicknesses of the high-voltage structures 136, the minimum thickness of the hybrid wafer 130 that is required for stability, and the thickness, if any, of the silicon wafer 110.

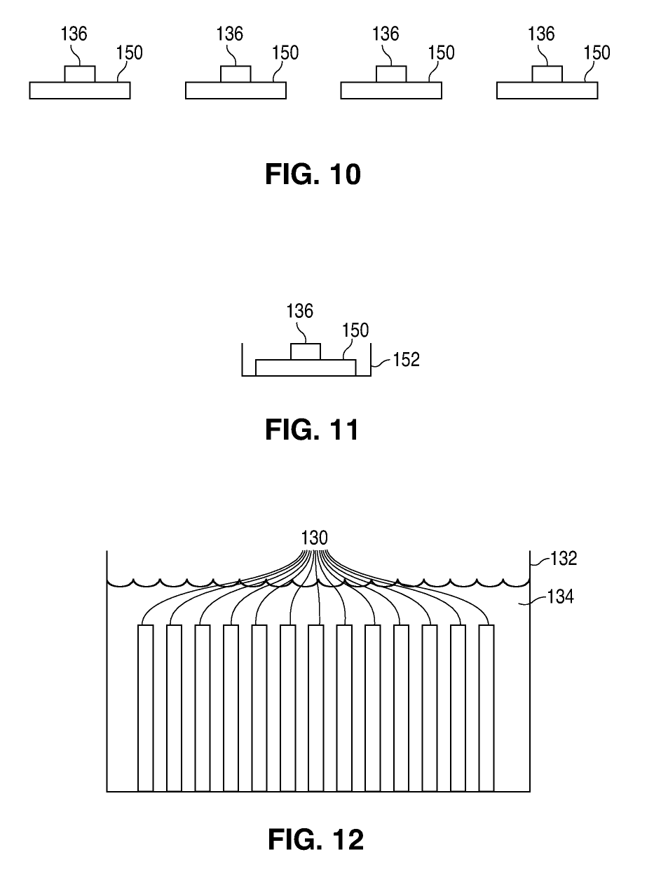

As shown in FIG. 10, once the silicon wafer 110 of the hybrid wafer 130 has been thinned or removed, the hybrid wafer 130 is diced to form a large number of individual die 150 that each has a high-voltage structure 136. As shown in FIG. 11, each individual die 150 is then attached to a package 152 that can accommodate a maximum die thickness in the range of approximately 250-400 μm in a conventional fashion.

Thus, prior to dicing, a completed hybrid wafer 130 of the present invention is functionally similar to completed quartz wafer and a completed deposited-oxide wafer (a silicon wafer with overlying layers of deposited silicon dioxide and high-voltage devices formed on the deposited silicon dioxide). The method of the present invention, however, forms functionally similar hybrid wafer 130 at a fraction of the cost required to form a completed quartz wafer or a completed deposited-oxide wafer.

In accordance with the present invention, the method forms a large number of hybrid wafers 130, and then, as shown in FIG. 12, simultaneously wet etches the large number of hybrid wafers 130 to achieve an economical result. Wet etching quartz is significantly less expensive than thinning quartz with a grinding wheel, or depositing silicon dioxide to thicknesses that approach 10 μm. Thus, by wet etching a large number of the hybrid wafers 130 at the same time, the present invention fabricates wafers with a throughput rate that can be equivalent to thinning quartz wafers or depositing oxide at a fraction of the cost.

It should be understood that the above descriptions are examples of the present invention, and that various alternatives of the invention described herein may be employed in practicing the invention. Therefore, it is intended that the following claims define the scope of the invention and that structures and methods within the scope of these claims and their equivalents be covered thereby.

What is claimed is:

1. A method of forming a semiconductor wafer comprising:
attaching a non-conductive wafer to a silicon wafer to form a hybrid wafer, a top surface of the non-conductive wafer forming a top surface of the hybrid wafer, a bottom surface of the silicon wafer forming a bottom surface of the hybrid wafer; and
wet etching the hybrid wafer so that all of the top surface of the non-conductive wafer is wet etched, the non-conductive wafer having a thickness after the hybrid wafer has been wet etched.

2. The method of claim 1 wherein none of the silicon wafer is removed by wet etching the hybrid wafer.

3. The method of claim 1 wherein an amount of the non-conductive wafer that is etched away by wet etching the hybrid wafer is substantially greater than an amount of the silicon wafer that is etched away by wet etching the hybrid wafer.

4. The method of claim 1 and further comprising forming a high-voltage structure that touches the top surface of the non-conductive wafer after the hybrid wafer has been wet etched.

5. The method of claim 4 wherein the high-voltage structure includes a conductive member.

6. The method of claim 5 and further comprising grinding the bottom surface of the hybrid wafer to thin the silicon wafer after the high-voltage structure has been formed.

7. The method of claim 6 and further comprising:
dicing the hybrid wafer to form a large number of individual die after the silicon wafer has been thinned; and
attaching an individual die to a package.

8. The method of claim 5 and further comprising grinding the bottom surface of the hybrid wafer to remove substantially all of the silicon wafer after the high-voltage structure has been formed.

9. The method of claim 8 and further comprising:
dicing the hybrid wafer to form a large number of individual die after the silicon wafer has been removed; and
attaching an individual die to a package.
